(19) United States
(12) Patent Application Publication
(10) Pub. No.: US 2018/0131324 A1
(43) Pub. Date: May 10, 2018

(54) High-Efficiency Ovenized Oscillator

(71) Applicant: Bliley Technologies, Inc., Erie, PA (US)

(72) Inventors: Stacie Granger, Erie, PA (US); Thomas J. Kopycinski, Erie, PA (US); Ken Martin, Erie, PA (US)

(21) Appl. No.: 15/677,185

(22) Filed: Aug. 15, 2017

Related U.S. Application Data
(60) Provisional application No. 62/375,074, filed on Aug. 15, 2016.

(51) Int. Cl. H03B 5/04; H03B 5/32; H05B 1/02

(52) U.S. Cl. CPC H03B 5/04; H05K 1/181; H05B 1/0288; H03B 5/32

(57) ABSTRACT

An ovenized crystal oscillator assembly includes an oscillator package defining a cavity which houses an interposer assembly. The interposer assembly, which can be housed in a recess in the base of the oscillator package, includes a quartz resonator and an interposer with a thin-film heater and temperature sensor. The quartz resonator is connected to the interposer on its edge(s) that is/are mounted to mechanical standoffs which are connected to electrical pads located on the interposer.

### CROSS REFERENCE TO RELATED APPLICATION

This application claims the benefit of U.S. Provisional Application No. 62/375,074, filed Aug. 15, 2016, entitled High-Efficiency Ovenized Oscillator, the contents of which are incorporated herein in its entirety by reference.

### BACKGROUND OF THE INVENTION

### Field of the Invention

The invention relates generally to oven controlled crystal oscillators and, more specifically, to a high-efficiency ovenized oscillator.

### Description of Related Art

Oscillators are known devices for providing a reference frequency source. The oscillator typically has a quartz crystal or other resonator and also has electronic compensation circuitry to stabilize the output frequency. Methods are known for stabilizing the output frequency as the temperature of the oscillator changes.

Oven controlled crystal oscillators (OCXO) heat the temperature sensitive portions of an oscillator in an enclosure or oven, defined by a base and a lid, to a uniform temperature. Ovenized oscillators contain a heater located in the oven, a temperature sensor, and circuitry on the substrate to control the heater.

Although currently available oscillators have proven satisfactory for some applications, there is a continued need for a more efficient oscillator, namely, one that allows for the integration of a high-efficiency heater in a conventional ovenized oscillator package and allows for the interposer and quartz resonator to operate in a more efficient manner.

### SUMMARY OF THE INVENTION

Generally, provided is an improved ovenized crystal oscillator.

Disclosed herein is an ovenized crystal oscillator that includes an oscillator package, which defines a cavity. Inside the cavity at the base of the oscillator package can be a recess where an interposer assembly resides. The interposer assembly can be formed to fit inside of the recess. The interposer assembly can include a resonator and an interposer with a thin-film heater and temperature sensor located on or embedded in a top surface of the interposer. The interposer can also include electrical contact pads on its top surface which are located around the thin-film heater and temperature sensor. Electrical contact pads can also be located within the oscillator package that connect the oscillator package to the interposer. The quartz resonator can be raised above the top surface of the interposer by mechanical standoffs. The quartz resonator can be mounted onto the standoffs using a conductive epoxy. The ovenized oscillator can also utilize electrical connections outside of the oscillator package to connect with the outside world.

Also disclosed herein is the integration of a high-efficiency heater interposer into a conventional ovenized oscillator package, which, in turn, can allow heat to be efficiently conducted from the heater to the quartz resonator. Furthermore, housing the interposer and quartz resonator within the oscillator package cavity allows for the assembly to be sealed and the surrounding environment can be evacuated, further improving heater efficiency and temperature control. Furthermore, the methods described herein for the design and assembly of the oscillator allow for thin-film and wafer scale processing techniques to be used.

According to one preferred and non-limiting embodiment or aspect, provided is an ovenized oscillator comprising: a package including a base; an interposer positioned on said base; a plurality of electrically conductive standoffs disposed on a side of the interposer opposite the base; a resonator positioned in spaced relation to the interposer by the plurality of electrically conductive standoffs; a thin-film resistive heater disposed on or in the interposer between the resonator and the base; and a temperature sensor disposed on or in the interposer between the resonator and the base.

The temperature sensor can be a temperature sensitive resistor. The temperature sensor can be positioned proximate to the thin-film resistive heater.

Conductive epoxy can be used to couple the resonator to the plurality of electrically conductive standoffs.

The package can include a roof or top and one or more side-walls. The roof or top, the one or more side-walls, and the base can define a cavity that houses the resonator.

The interposer can be formed of a material that is an electrical insulator.

The base can have one or more steps defining a recess. The interposer can be positioned in the recess.

A plurality of electrical connections can be provided. Each electrically conductive standoffs can be electrically connected to at least one of the electrical connections. The thin-film resistive heater can electrically connected to at least one of the electrical connections. The temperature sensitive resistor can be electrically connected to at least one of the electrical connections.

Further preferred and non-limiting embodiments or aspects are set forth in the following numbered clauses.

Clause 1: According to one preferred and non-limiting embodiment or aspect, provided is an ovenized oscillator comprising: a package including a base; an interposer positioned on said base; a plurality of electrically conductive standoffs disposed on a side of the interposer opposite the base; a resonator positioned in spaced relation to the interposer by the plurality of electrically conductive standoffs; a thin-film resistive heater disposed on or in the interposer between the resonator and the base; and a temperature sensor disposed on or in the interposer between the resonator and the base.

Clause 2: The ovenized oscillator of clause 1, wherein the temperature sensor can be a temperature sensitive resistor; and the temperature sensor can be positioned proximate to the thin-film resistive heater.

Clause 3: The ovenized oscillator of clause 1 or 2, further including a conductive epoxy coupling the resonator to the plurality of electrically conductive standoffs.

Clause 4: The ovenized oscillator of any one of clauses 1-3, wherein: the package includes a roof or top and one or more side-walls; and the roof or top, the one or more side-walls, and the base define a cavity that houses the resonator.

Clause 5: The ovenized oscillator of any one of clauses 1-4, wherein the interposer is formed of a material that is an electrical insulator.

Clause 6: The ovenized oscillator of any one of clauses 1-5, wherein: the base has one or more steps defining a recess; and the interposer is positioned in the recess.

Clause 7: The ovenized oscillator of any one of clauses 1-6, further including: a plurality of electrical connections, wherein: each electrically conductive standoffs is electrically connected to at least one of the electrical connections, the thin-film resistive heater is electrically connected to at least one of the electrical connections, and the temperature sensitive resistor is electrically connected to at least one of the electrical connections.

### BRIEF DESCRIPTION OF THE DRAWING

FIG. 1 is a cross-sectional schematic view of an example ovenized crystal oscillator comprising a quartz resonator and an interposer with an embedded thin-film heater and a temperature sensor.

### DESCRIPTION OF THE INVENTION

Various non-limiting examples will now be described with reference to the accompanying FIGURES where like reference numbers correspond to like or functionally equivalent elements.

For purposes of the description hereinafter, the terms “end,” “upper,” “lower,” “right,” “left,” “vertical,” “horizontal,” “top,” “bottom,” “lateral,” “longitudinal,” and derivatives thereof shall relate to the example(s) as oriented in the drawing FIGURES. However, it is to be understood that the example(s) may assume various alternative variations and step sequences, except where expressly specified to the contrary. It is also to be understood that the specific example(s) illustrated in the attached drawings, and described in the following specification, are simply exemplary examples or aspects of the invention. Hence, the specific examples or aspects disclosed herein are not to be construed as limiting.

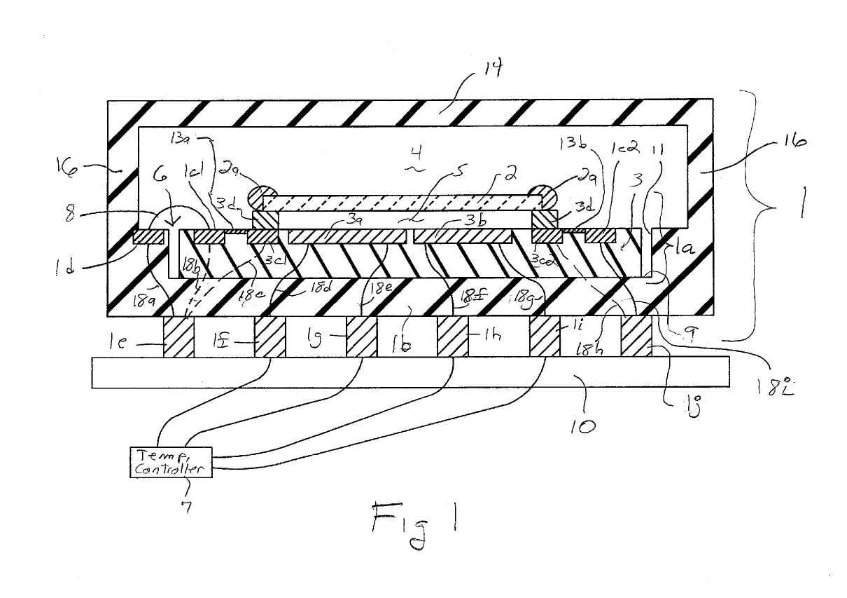

FIG. 1 depicts an example of a high-efficiency ovenized oscillator that includes an oven controlled crystal oscillator (OCXO) assembly.

In an example, the ovenized crystal oscillator 1 can include the following components; an oscillator package 1b defining a cavity 4; an interposer 3 located, seated, or mounted on and against a top surface of a base 9 of cavity 4 of oscillator package 1b; a thin-film heater 3a located on, seated, or embedded in a top surface of interposer 3; a temperature sensor 3b located on, seated, or embedded in the top surface of interposer 3 and next to thin-film heater 3a; and a quartz resonator 2 positioned and raised above interposer 3 leaving a space 5 between a bottom surface of quartz resonator 2 and the top surface of interposer 3. In an example, thin-film heater 3a can be square or rectangular in shape. However, this is not to be construed in a limiting sense.

In an example, oscillator package 1b can form the shape of a square or rectangular box-like structure defining cavity 4. Cavity 4 can be defined by a roof or top 14 and one or more, e.g. four, downwardly-extending side walls 16 that meet with a bottom or base 9 of oscillator package 1b. In an example, cavity 4 of oscillator package 1b can be sealed in a manner known in the art from outside environments to protect cavity 4 from the outside environment. In an example, cavity 4 of oscillator package 1b can also be evacuated under a vacuum. This can be done so that the heating efficiency and temperature control of oscillator 1 can be accurately controlled.

In an example, cavity 4 of oscillator package 1b can be in the shape of an outside appearance of oscillator package 1b. Cavity 4 of oscillator package 1b can house an interposer assembly 1a. Interposer assembly 1a can sit in cavity 4 on base 9 of oscillator package 1b. Base 9 of cavity 4 within oscillator package 1b can include one or more steps 12 that can form a recess 6 for receiving interposer 3. Recess 6 can be defined by two or more steps 12 or a continuous step 12 around the interior periphery of cavity 4 along the lower inside of cavity 4 of oscillator package 1b. The vertical faces 11 of the step(s) 12 defining recess 6 as well as the top surface of base 9 of recess 6 of cavity 4 of oscillator package 1b can be formed to fit outside of or around interposer 3, thereby forming a place for holding interposer assembly 1a. Interposer 3 can be coupled to base 9 of recess 6 of cavity 4 of oscillator package 1b in any suitable and/or desirable manner known in the art. One such example of how interposer 3 can be coupled to base 9 of oscillator package 1b in recess 6 of cavity 4 can be with the use of an epoxy (not shown).

The base of interposer assembly 1a can include interposer 3 which can be comprised of, for example, a substrate of glass, alumina, or any other suitable and/or desirable electrically insulative material. Interposer 3 can be located in recess 6 of cavity 4 of oscillator assembly 1b and can be seated on the top surface of base 9 of oscillator assembly 1b. Interposer 3 can be square or rectangular box-shaped with the bottom of interposer 3 coupled to base 9 of cavity 4 via, for example, an epoxy, and can be sized to fit within recess 6 at base 9 of cavity 4 in oscillator package 1b.

In an example, interposer 3 can include on a top surface thereof or embedded in said top surface a thin-film heater 3a which can be formed on interposer 3 in any suitable and/or desirable manner, such as, without limitation, thin-film wafer processing techniques. Temperature sensor 3b can be on the top surface of interposer 3 or embedded in top surface of interposer 3 and formed on interposer 3 in any suitable and/or desirable manner, such as, without limitation, thin-film wafer processing techniques. In an example, thin-film heater 3a can be a resistive heater and temperature sensor 3b can be a temperature sensitive resistor with a known temperature-resistance relationship.

Temperature sensor 3b and thin-film heater 3a can be located next to each other embedded in or on the top surface of interposer 3. The example in FIG. 1 shows thin-film heater 3a embedded in the left center portion of top surface of interposer 3 and temperature sensor 3b embedded in the right center portion adjacent thin-film heater 3a. However, these positions are not limited to this orientation. In an example, thin-film heater 3a and temperature sensor 3b can be embedded in the top surface of interposer 3 by first depositing thin-film heater 3a and temperature sensor 3b (in any order) on the top surface of interposer 3 and, thereafter, depositing metallization and passivation layers around thin-film heater 3a and temperature sensor 3b, with a passivation layer being the top-most layer. Regardless of the process used to embed thin-film heater 3a and temperature sensor 3b in the top surface of interposer 3, the process is, in an example, an additive process.

Oscillator package 1b can also house quartz resonator 2. Via a conductive epoxy 2a quartz resonator 2 can be mounted to a plurality of mechanical standoffs 3d which hold quartz resonator 2 above interposer 3 and allow the quartz resonator 2 to resonate. Epoxy 2a can be used for coupling quartz resonator 2 to mechanical standoffs 3d. Epoxy 2a also provides a thermal path that facilitates temperature sensor 3b monitoring the temperature of quartz resonator 2 and an electrically conductive path from interposer assembly 1a to quartz resonator 2. Quartz resonator 2 can be positioned in spaced relation above interposer 3 top surface and can define a space 5 between the top surface of interposer 3 and the bottom surface of quartz resonator 2. The bottom surface of quartz resonator 2 can be parallel to the top surface of interposer 3.

An external temperature controller 7 can control thin-film heater 3a. Temperature controller 7 controls thin-film heater 3a to heat and maintain quartz resonator 2 within a desired predetermined temperature range within cavity 4 of oscillator package 1b. More specifically, temperature controller 7 can be connected to temperature sensor 3b and thin-film heater 3a via internal conductors 18d-18g and electrical connections 1f-1i via an outside substrate 10, such as a PCB, in a manner known in the art. Temperature controller 7 monitors the temperature inside cavity 4 of oscillator package 1b via temperature sensor 3b which, in an example, has a resistance value related to said temperature. When temperature controller 7 detects, via the resistance of temperature sensor 3b, that the temperature is below the desired temperature range, temperature controller 7 can increase the power supplied to thin-film heater 3a to increase the temperature within oscillator package 1b to within the desired temperature range. When the temperature is above the desired temperature range, temperature controller 7 can reduce or withhold power to thin-film heater 3a to allow for a decrease in the temperature within oscillator package 1b to within the desired temperature range. The desired temperature range can have an upper limit and a lower limit. Both the upper limit and the lower limit of the desired temperature range can have its own value. The difference between the upper limit and lower limit values can be small to negligible. By providing a stable temperature inside oscillator package 1b via thin-film heater 3a, temperature sensor 3b, and temperature controller 7, quartz resonator 2 can oscillate at a stable reference frequency regardless of the temperature external to oscillator package 1b.

Quartz resonator 2, via mechanical standoffs 3d, can be electrically and mechanically connected to electrical pads 3c on or embedded in the top surface of interposer 3 between the outside edge of interposer 3 and both heater 3a and temperature sensor 3b. Some or all of mechanical standoffs 3d, which are connected to electrical pads 3c, can be electrically conductive or can include a coating or film of electrically conductive material. Additional mechanical standoffs 3d can be utilized to ensure better mechanical stability of quartz resonator 2. These additional mechanical standoffs 3d can be either electrically conductive or non-conductive. In an example, electrical pads 3c can be located so that the center of each electrical pad 3c can be located a specified distance away from another electrical pad 3c a distance equivalent to the length of quartz resonator 2. Mechanical standoffs 3d are located atop of electrical pads 3c that can be equivalent in distance apart from each other to the length of quartz resonator 2. Therefore, mechanical standoffs 3d can be located an equivalent distance apart from each other so that they not only connect to electrical pads 3c located outside of heater 3a and temperature sensor 3b but also so that mechanical standoffs 3d are located below the ends of quartz resonator 2.

Heat from thin-film heater 3a can be conducted to quartz resonator 2 via conduction, convection, or radiation via space 5 and/or via electric pads 3c on the top surface of interposer 3 and mechanical standoffs 3d connected to ends of quartz resonator 2.

In an example, oscillator package 1b can have electrical connectors 1e-1j located outside of oscillator package 1b. In an example, electrical connectors 1e and 1j can be electrically connected to electrical pads 3c1 and 3c2 shown in FIG. 1 in any suitable and/or desirable manner. In one example, one or both electrical connectors 1e and 1j can be can be directly electrically connected to electrical pads 3c1 and 3c2 via internal conductors 18c and 18h (shown in phantom) of oscillator package 1b.

In another example, one or both electrical connectors 1e and 1j can be can be electrically connected to the pair of electrical pads 3c1 and 3c2 via internal conductors 18b (shown in phantom) and 18i (shown in solid line) of oscillator package 1b, optional electrical pads 1c1 and 1c2, and optional electrical contacts 13a and 13b. In this example, optional electrical pads 1c1 and 1c2, and optional electrical contacts 13a and 13b can be extensions of electrical pads 3c1 and 3c2. A benefit of having each electrical pad 1c1 and 1c2 spaced from its respective electrical pad 3c1 and 3c2 is that it (electrical pad 1c1 or 1c2) can, via the corresponding electrical contact 13a or 13b, be positioned on or in interposer 3 at any suitable and/or desirable location that facilitates electrical connection (and mechanical routing) to its corresponding electrical conductor 1e or 1j.

In yet another example, one or more steps 12 can each include (on a top surface thereof) an electrical bonding pad 1d which can be connected to an electrical pad 1c via a wire bond 8. FIG. 1 shows a single electrical bonding pad 1d: (1) electrically connected to electrical pad 1c1 via wire bond 8, and (2) electrically connected to electrical connector 1e via internal conductor 18a. However, this is not to be construed in a limiting sense since it is envisioned that multiple bonding pads 1d and wire bonds can be provided for creating a number of electrical paths between electrical pads 1c and electrical connections, 1e, 1j (for example).

In an example, the use of any combination of the various means described above to electrically connect electrical pads 3c1 and 3c2 to electrical connectors 1e and 1j can be used—as shown by internal conductors 18a and 18i having solid lines, and internal conductors 18b, 18c, and 18h having dashed lines. Hence, the manner in which electrical pads 3c1 and 3c2 are electrically connected to electrical connectors 1e and 1j is not to be construed in a limiting sense.

In an example, the provided internal conductors 18 can extend through base 9 of oscillator package 1b. However, is not to be construed in a limiting sense. Moreover, while FIG. 1 schematically illustrates internal conductors 18 extending through interposer 3, this is not to be construed in a limiting sense since each internal conductor can alternatively extend around a side of interposer 3.

In this regard, the schematic illustration of internal conductors 18 and their paths extending through base 9 of oscillator package 1b and/or through interposer 3 is for the purpose of illustration and description only and is not to be construed in a limiting sense since each internal conductor 18 (or part thereof) can be implemented and routed in any suitable and/or desirable manner now known or hereinafter developed by one of ordinary skill in the art. For example, each internal conductor 18 can be an electrical lead of the type commonly found on integrated circuit packages. In an example, oscillator package 1b can includes a number of electrical leads of the type commonly found as part of an integrated circuit package, and each electrical lead of oscillator package 1b can be formed from one internal conductor, e.g., 18d, and its corresponding electrical connectors, e.g., 1f. However, this is not to be construed in a limiting sense.

As can be seen, disclosed herein is an ovenized oscillator comprising: a package 1b including a base 9; an interposer 3 positioned on said base 9; a plurality of electrically conductive standoffs 3d disposed on a side of the interposer 3 opposite the base 9; a resonator 2 positioned in spaced relation to the interposer 3 by the plurality of electrically conductive standoffs 3d; a thin-film resistive heater 3a disposed on or in the interposer 3 between the resonator 2 and the base 9; and a temperature sensor 3b disposed on or in the interposer 3 between the resonator 2 and the base 9.

The temperature sensor 3b can be a temperature sensitive resistor. The temperature sensor 3b can be positioned proximate to the thin-film resistive heater 3a.

Conductive epoxy can be used to couple the resonator 2 to the plurality of electrically conductive standoffs 3d.

The package 1b can include includes a roof or top 14 and one or more side-walls 16. The roof or top 14, the one or more side-walls 16, and the base 9 can define a cavity 4 that houses the resonator 2.

The interposer can be formed of a material that is an electrical insulator.

The base 9 can have one or more steps 12 defining a recess 6. The interposer 3 can be positioned in the recess 6.

A plurality of electrical connections 1e-1j can be provided. Each electrically conductive standoffs 3d can be electrically connected to at least one of the electrical connections 1e-1h. The thin-film resistive heater 3a can electrically connected to at least one of the electrical connections 1e-1h. The temperature sensitive resistor 3b can be electrically connected to at least one of the electrical connections 1e-1h.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The invention claimed is:

1. An ovenized oscillator comprising:
a package including a base;
an interposer positioned on said base;
a plurality of electrically conductive standoffs disposed on a side of the interposer opposite the base;
a resonator positioned in spaced relation to the interposer by the plurality of electrically conductive standoffs;
a thin-film resistive heater disposed on or in the interposer between the resonator and the base; and
a temperature sensor disposed on or in the interposer between the resonator and the base.

2. The ovenized oscillator of claim 1, wherein:
the temperature sensor is a temperature sensitive resistor; and
the temperature sensor is positioned proximate to the thin-film resistive heater.

3. The ovenized oscillator of claim 1, further including a conductive epoxy coupling the resonator to the plurality of electrically conductive standoffs.

4. The ovenized oscillator of claim 1, wherein:
the package includes a roof or top and one or more side-walls; and
the roof or top, the one or more side-walls, and the base define a cavity that houses the resonator.

5. The ovenized oscillator of claim 1, wherein the interposer is formed of a material that is an electrical insulator.

6. The ovenized oscillator of claim 1, wherein:
the base has one or more steps defining a recess; and
the interposer is positioned in the recess.

7. The ovenized oscillator of claim 1, further including:
a plurality of electrical connections, wherein:
each electrically conductive standoffs is electrically connected to at least one of the electrical connections,
the thin-film resistive heater is electrically connected to at least one of the electrical connections, and
the temperature sensitive resistor is electrically connected to at least one of the electrical connections.
